(19) United States
(12) Patent Application Publication
(10) Pub. No.: US 2026/0366148 A1
(43) Pub. Date: Nov. 19, 2026

(54) METHOD AND DEVICE FOR DEPOSITING LAYERS ON A SUBSTRATE

(71) Applicant: AIXTRON SE, Herzogenrath (DE)

(72) Inventors: Pitsiri BOOKER, Aachen (DE); Philip HENS, Obermichelbach (DE); Peter Sebald LAUFFER, Aachen (DE)

(21) Appl. No.: 19/137,061

(22) PCT Filed: Dec. 6, 2023
(86) PCT No.: PCT/EP2023/084516

§ 371 Date: Jun. 9, 2025

(30) Foreign Application Priority Data
Dec. 9, 2022 (DE) 10 2022 132 776.0

(51) Int. Cl. C23C 16/32; C23C 16/455; C23C 16/458

(52) U.S. Cl. CPC C23C 16/325; C23C 16/45508; C23C 16/4584

(57) ABSTRACT

A method for depositing a layer on a substrate. A homogeneous first gas flow is fed by means of a gas-inlet member into a process chamber that has been brought to a process temperature. The first gas flow flows over the substrate in a flow direction and contains one or more reactive gases, the decomposition products of which form the layer. A second gas flow is fed into the process chamber through a gas-outlet area of a gas-outlet opening arranged downstream of the gas-inlet member and upstream of the substrate, and contains at least one gas that influences a dopant concentration within the layer. The width, extending transversely to the flow direction, of the gas-outlet opening is less than the width, extending transversely to the flow direction, of the substrate. A gas that influences the composition of the layer flows through the gas-outlet opening.

### RELATED APPLICATIONS

This application is a National Stage under 35 USC 371 of and claims priority to International Application No. PCT/EP2023/084516, filed 6 Dec. 2023, which claims the priority benefit of DE Application No. 10 2022 132 776.0, filed 9 Dec. 2022.

### FIELD OF THE INVENTION

The invention relates to a method and a device for depositing a layer on a substrate, wherein a homogeneous gas flow is fed via a gas-inlet element into a process chamber brought to a process temperature. The gas flow passes evenly in laminar flow over the cross-sectional area of the process chamber in a uniform flow direction, wherein the flow lines of the gas flow may run parallel to one another or in radial direction to a center. The gas flow flowing in a flow direction over the substrate contains one or more reactive gases, the decomposition products of which form the layer to be deposited on the substrate. A second gas flow flows into the process chamber through an additional gas-outlet opening, which is arranged downstream of the gas-inlet element and upstream of the substrate or a substrate holder carrying the substrate. The second gas flow contains a reactive gas that influences a layer composition within the layer, for example a dopant.

### BACKGROUND

DE 10 2018 124 957 A1 describes a device for depositing semiconductor layers, with a process chamber, in the center of which there is a gas-inlet element with which a process gas is fed into the process chamber, which spreads in a radial direction in the process chamber and flows over substrates arranged around the gas-inlet element. The substrates are supported by substrate holders, which are supported by a purge gas. The purge gas is not only able to set the substrate holders into a rotary motion, by varying the purge gas flow the transport of heat to the substrate holder can also be influenced. Upstream of each substrate holder, there is a gas-inlet opening through which a compensating gas is fed into the process chamber, with which the fluctuations in the purge gas can be compensated.

U.S. Pat. No. 8,052,794 B2 describes a device and a method for depositing SiC. The method is carried out at process temperatures higher than 1600 degrees Celsius. A silicon-containing and a carbon-containing reactive gas are fed into the process chamber through a gas-inlet element as reactive gases. In addition, a gaseous dopant in the form of nitrogen N₂ is fed through the gas-inlet element.

A similar device is described in U.S. Pat. No. 10,930,492 B2. In both devices, the substrates are supported by substrate holders arranged on a susceptor, which are kept suspended by a purge gas. A gas that influences the dopant concentration within the layer is mixed into the purge gas in order to influence the dopant incorporation in the layer.

U.S. Pat. No. 10,858,758 B2 describes a CVD reactor for depositing SiC layers, with a gas-inlet element that is arranged upstream of a substrate in the flow direction. The gas-inlet element has a gas-inlet outlet surface whose width is greater than the width of the substrate. The gas-outlet surface is divided into three zones, through each of which a mixture of hydrogen, propane, monosilane and nitrogen can be fed into the process chamber, wherein the mixtures in the three zones may differ.

The objective of the last-described method is to ensure that the SiC layers deposited on the substrate have the most homogeneous dopant concentration possible. In SiC layers that are deposited without the additional feeding of the dopant into the purge gas that creates the gas cushion, a dopant concentration that increases towards the edge of the layer was observed. This inhomogeneity of the dopant incorporation is to be reduced with the measures described above.

### SUMMARY OF THE INVENTION

The invention is based on the object of further improving the homogeneity of the dopant concentration within the layer and, in particular, of specifying means with which the layer composition within the layer can be influenced locally in a targeted manner.

The object is achieved by the invention specified in the claims, wherein the subclaims are not only advantageous developments of the invention specified in the independent claims, but also represent independent solutions to the object.

Whereas in the prior art an additional gas flow is generated which contains a gas that influences the dopant concentration within the layer and which exits from a gas-outlet surface which is wider than the width of the substrate extending transversely to the flow direction, the invention suggests reducing the width of the gas-outlet surface so that it is smaller than the width of the substrate. As a result, a gas flow is formed which flows along a flow line running in the flow direction and in which the concentration of a dopant, for example, differs from the neighboring gas flow. The gas flow flowing along the flow line may expand due to diffusion effects. It influences the incorporation of dopant in the layer on a locally limited area on the surface of the substrate. The gas-inlet element according to the invention has a gas-outlet surface on which gas-outlet openings are arranged in such a way that a gas flow that is as homogeneous as possible can be fed into the process chamber. The effective width of the gas-inlet element is greater than the width of the substrate extending transversely to the flow direction, so that a laminar first gas flow emerges from the gas-outlet surface of the gas-inlet element, which flows through the process chamber in a uniform flow direction. The flow lines of the first gas flow, which extend in a straight line from the gas-inlet element until over the substrate, may run parallel to one another or emerge from the gas-inlet element in a star shape, i.e. in a radial direction relative to a center of the process chamber. In the first gas flow, the concentration of its components is distributed homogeneously over the entire cross-sectional area. In order to achieve this, the gas-inlet element preferably has a gas-outlet surface which has a large number of gas passage openings which are evenly distributed thereon and have identical areas to one another. It may be provided that the concentration of the first gas flow differs in the vertical direction if, for example, different reactive gases are fed in at different horizontal levels. Within these horizontal levels, however, the gas flow is homogeneous in each case. According to the invention, a second gas flow is fed into such a homogeneous first gas flow downstream of the gas-inlet element and upstream of the substrate. For this purpose, a gas-outlet opening is used of which the width is smaller than the width of the substrate. As a result, a local gas flow of the dopant is formed which influences the substrate only on a partial surface. The position of the partial surface depends on where the at least one gas-outlet opening is arranged on a line running transversely to the flow direction. For example, if the gas-outlet opening is arranged on a midline which extends in the flow direction of the first gas flow exiting the gas-inlet element through the middle point of the substrate, the incorporation of the dopant within the layer in the center of the substrate changes. If, on the other hand, the gas-outlet opening is arranged with an offset relative to the midline, the incorporation of the dopant increases in a region of the layer that is at a distance from the center of the substrate. The flow line of the second gas flow generated by the gas-outlet surface can pass over the substrate in a region that extends between the middle point of the substrate and a point on the edge of the substrate that lies on a line running through the middle point of the substrate and transverse to the flow direction. However, it may also be provided that the flow line extends outside the edge of the substrate, so that the second gas flow flows past the substrate. In this case, the gas that influences the layer composition, in particular the dopant concentration, substantially only influences the edge of the substrate. In a CVD reactor that has a central gas-inlet element, the gas-outlet opening may be located on a flow line that is offset by an angle relative to the midline running through the middle point of the substrate in the direction of flow. The angle may be selected such that the gas flow flows over a partial area of the substrate that lies between the middle point and the edge of the substrate. However, the gas flow may also flow past the substrate. If multiple substrates are located next to each other, for example in a circumferential line around the center of the process chamber, the second gas flow may also flow through a gap between two substrates, for example through the middle of this gap. In a CVD reactor through which the first gas flow does not flow in a star shape, but linearly, the at least one gas-outlet opening may be offset by a distance from the midline passing through the middle point of the substrate in the direction of flow. Alternatively, the gas-outlet opening may also impart an impulse to the second gas flow so that its direction deviates from the flow direction of the first gas flow, for example a borehole forming the gas-outlet opening may extend at an angle to the surface normal of the susceptor surface. In the first case, the angle influences the effective site of the second gas flow, in the second case the length of the distance of separation influences the position of the effective site of the second gas flow on the substrate. In the third case, the direction of an outlet channel that opens in the outlet opening influences the effective site of the second gas flow. According to a preferred development of the invention, it is suggested that the width of the gas-outlet surface of the gas-outlet opening extending transversely to the flow direction is smaller than half, a third, a quarter, a fifth or a sixth of the width of the substrate extending transversely to the flow direction. The smaller the width of the gas-outlet surface of the gas-outlet opening is, the more precisely the composition of the layer and in particular the dopant incorporation in the layer can be influenced locally with one or more gas-outlet openings. But the gas-outlet surface may also be composed of multiple partial openings with different individual surfaces. The composition of a layer composed of multiple components may be influenced locally using the method described above. The method is preferably used to influence the dopant incorporation. The width of the gas-outlet opening may also be used as a means of influencing the mass flow of the second gas flow, for example in the manner of a throttle. For this purpose, a combination of different individual openings may be provided which have the same opening area as each other or different opening areas. This makes it possible to influence the size and shape of the zone on which the substrate is influenced by the second gas flow. The method according to the invention is preferably used when depositing SiC layers on substrates, for example SiC substrates, as already described in the above-mentioned prior art, i.e. at temperatures which are greater than, for example, 1500 degrees Celsius. At least one carbon-containing gas, for example methane, propane or the like, and a silicon-containing gas, for example monosilane, disilane or trichlorosilane, are used as reactive gases. However, it is also possible to use Si(CH₃)₄). The SiC layer is to be doped with nitrogen. A nitrogen-containing gas such as ammonia or N₂ may be used as a gas influencing the dopant concentration within the layer. The method can be used not only for N-doping, but also for P-doping. Instead of nitrogen, other dopants may also be used, for example aluminum, boron, for example in the form of TMAl or TEB or another suitable Al or B compound. However, it is also provided that a carbon-containing gas such as methane, propane or the like is used as the gas influencing the dopant concentration within the layer. Whereas when a gas containing the dopant is used, the dopant concentration in the layer increases substantially proportionally to the partial pressure of the gas or the dopant immediately above the substrate, when the carbon-containing gas is used the incorporation of dopant in the layer is reduced substantially in reciprocal proportion to the partial pressure of the gas or the substance preventing the dopant incorporation immediately above the substrate. With the use of N₂, for example, dopant incorporation can be increased locally. By using methane or propane, for example, dopant incorporation can be reduced locally. In order to counteract the problem of the higher dopant concentration at the edge of the layer mentioned in the introduction, it may therefore be beneficial to arrange the outlet opening offset by an angle to the midline or offset by a distance to the midline such that the flow line on which the second gas flow passing through the gas-outlet opening flows runs over the substrate between the midline and the edge of the substrate. This is particularly advantageous if the second gas flow contains N₂, and the dopant concentration without the second gas flow has a W-shaped course over a diameter of the layer. The dopant concentration in the layer then has a maximum in each of the area of the middle point and the edge of the substrate. The dopant concentration has a minimum between the middle point and the edge of the substrate. The angle or distance is chosen such that the flow line of the second gas flow passes through this minimum, so that the dopant incorporation is specifically favored here. In the case of a rotating susceptor, the areas exerted on the gas flow by the rotation must also be taken into account. If, on the other hand, the dopant concentration without the second gas flow has a U-shaped course over a diameter of the layer, i.e. a minimum in the region of the middle point and a maximum in the area of the edge, the second gas flow may contain a reactive gas that suppresses the dopant incorporation, for example a carbon-containing gas. It is then advantageous if the second gas flow is only limited to the edge of the substrate. For this purpose, it may be beneficial to allow the second gas flow to flow past the substrate directly at the edge of the substrate. It may also be advantageous to allow the second gas flow to flow through a gap between two substrates, preferably in the middle. This reduces the dopant incorporation in targeted manner in the edge area of the substrate. The gas-outlet opening may be located at a distance from the substrate or a substrate holder carrying the substrate.

The gas-outlet opening may be a circular borehole in the susceptor that is connected to a supply line. In the case of a rotationally symmetrical arrangement, the borehole or the multiple boreholes, each assigned to a substrate, may be arranged in a ring that surrounds the gas-inlet element. If this ring is movable in an azimuthal direction, the position of the gas-outlet opening can be changed. In a process chamber with linear flow, the boreholes may also be arranged on a movable plate, so that the distance between the gas-outlet opening and the midline can be adjusted by moving the plate. The device used to perform the method may include a susceptor that is driven to rotate around its center. In the susceptor, pockets may be evenly distributed in the circumferential direction around the center, each of which containing a substrate holder. Purge gas flows that contain only an inert gas, for example hydrogen, may be fed into the bottom of the pockets. This purge gas serves to create a gas cushion that supports the respective substrate holder and causes it to rotate, wherein the rotation speed of the substrate holder is greater than the rotation speed of the susceptor. Due to the rotation of the substrate holder, a layer that is rotationally symmetrical in terms of its properties is formed on the substrate. By the selection of angle and/or separation and of the width of the gas-outlet opening measured transversely to the flow direction, the dopant incorporation can be influenced in targeted manner in radial zones. It may be provided that only an inert gas, for example hydrogen and a carbon-containing and a silicon-containing gas, is fed into the process chamber through the gas-inlet element. The dopant is then incorporated into the layer exclusively with reactive gases, which exit through one or more gas-outlet openings of the type and arrangement described above. For this purpose, it may be advantageous for multiple gas-outlet openings to be arranged for one, preferably each substrate, in particular on a line running transversely to the flow direction, which may be a straight line or a circular arc. The dopant incorporation can be influenced locally in targeted manner through the various gas-outlet openings. However, it may also be provided that different gas flows flow through different gas-outlet openings and in particular gas-outlet openings assigned to different substrates, wherein the flows may differ in terms of mass flow. Preferably, the partial pressure of the reactive gas within the gas flow is the same in all flows. However, it is also provided that a reactive gas containing the dopant is additionally fed in through the gas-inlet element and that the dopant incorporation is locally influenced by the second gas flow. For this purpose, it is considered advantageous if the second gas flow dehomogenizes a previously homogeneous gas flow. The device may include a gas-outlet element that is arranged downstream of the substrate or the substrate holder in the flow direction of the gas flows. In a rotationally symmetrical arrangement of the susceptor and gas-inlet element, the gas-outlet element may surround the susceptor in a ring such that an edge of the susceptor extending on a circular arc line borders the gas-outlet element. A gas discharge line may connect the gas-outlet element to a pump with which the total pressure within the process chamber can be set to a negative pressure. The process chamber is preferably heated with a heating device. The heating device may be an RF coil that heats the susceptor, which may be made of graphite and generate eddy currents in the susceptor. A process chamber ceiling may be heated by heat radiation from the susceptor, or the process chamber ceiling may also be heated actively. By feeding the reactive gases into the process chamber, decomposition products, for example Si, C and N or intermediate products containing these elements, are created due to the increased temperature, and diffuse through a boundary layer of the process gas above the substrate to the substrate surface, where they react with the surface of the substrate or the layer already deposited thereon to form a nitrogen-doped SiC layer. The reactive gas that influences the layer composition can be fed into the process chamber by other means as well as through the supplementary gas-outlet opening. It is also provided that this reactive gas is also fed into the process chamber through the gas-inlet element, so that the supply to the substrate surface is modulated locally with the gas flow emerging from the gas-outlet opening. The device for performing the method may have six bearing positions for substrates arranged evenly about the center. The angle by which the flow line is offset with respect to the midline may be in the range between 5 and 10 degrees. The preferred angle may be 8.5 degrees. In this case, the circular substrate may lie at a sector angle of 70 degrees, so that a tangent passing through the center to the edge of the substrate extends at an angle of 35 degrees to the midline.

The invention further relates to a method for depositing a layer on a substrate, with a process chamber that is delimited at the bottom by a susceptor and at the top by a process chamber ceiling. Process gases are fed into the process chamber through a gas-inlet element. The process gases flow through the process chamber in horizontal direction. The gas-inlet element may include multiple gas-inlet zones arranged vertically one above the other, through which various reactive gases can enter the process chamber separately from one another. The reactive gases may contain silicon and carbon, may be for example trichlorosilane or H₂H₄. Ammonia may also be fed into the process chamber as a dopant through one of the gas-inlet zones. This may be through a gas-inlet zone arranged at the top. But the ammonia can also be fed into the process chamber through any other gas-inlet zone, for example through a middle gas-inlet zone, located at a distance from the process chamber ceiling and the susceptor.

A further doping gas may be fed into the process chamber through a gas-outlet opening in the bottom of the process chamber, in particular a gas-outlet opening such as was described above. Through this gas-outlet opening, which may have fundamentally the same properties as the gas-outlet opening described above, it is preferred to feed in nitrogen (molecular nitrogen N₂). The nitrogen thus flows through a lowest region of the process chamber.

NH₃ and N₂ may be fed in at different positions. The two doping gases may be fed into the process chamber through any of the multiple gas-inlet zones arranged one above the other. It is provided in particular that NH₃ or HCN or pyridine (C₅H₅N), hydrazine (N₂H₄) or dimethylhydrazine (C₂H₃N₂) or unsymmetrical dimethylhydrazine is fed into the process chamber through one or more gas-inlet zones. Different doping gases may be fed in through different gas-inlet zones.

It is provided in particular that NH₃ or another of the above-mentioned doping gases is fed into the process chamber through the gas-inlet element. This may take place at different vertical heights, for example through the uppermost gas-inlet element, through a gas-inlet element located in the middle or through a gas-inlet element located at the bottom.

In addition, NH₂ may be fed into the process chamber from the gas-outlet opening arranged in the bottom of the process chamber, i.e. in the susceptor.

However, it is also possible to feed NH₃ through this gas-outlet opening. In particular, it is possible to feed in NH₃ through the lowest gas-inlet zone and NH₃ through the gas-outlet opening simultaneously.

### BRIEF DESCRIPTION OF THE DRAWINGS

Embodiments of the invention are explained below with reference to the accompanying drawings. In the drawings:

FIG. 1 shows a schematic cross section through a CVD reactor for performing the method,

FIG. 2 shows a plan view approximately along the section plane II-II of a susceptor 2,

FIG. 3 shows the section of the first embodiment designated III in FIG. 2,

FIG. 4 shows the section shown in FIG. 3 from a second embodiment,

FIG. 5 shows the section shown in FIG. 3 from a third embodiment,

FIG. 6 shows a schematic representation of the course of a dopant concentration in a layer on a line d extending through the middle point 12 of the substrate 9 in each case, wherein the second gas flow contains a gas that enhances dopant incorporation,

FIG. 7 shows a schematic representation of the course of a dopant concentration in a layer on a line d extending through the middle point 12 of the substrate 9 in each case, wherein the second gas flow contains a gas that reduces dopant incorporation,

FIG. 8 shows the section shown in FIG. 3 from a fourth embodiment,

FIG. 9 shows a schematic cross section through a CVD reactor for performing the method from the fifth embodiment,

FIG. 10 shows a plan view of the susceptor of the CVD reactor of the fifth embodiment,

FIG. 11 is a representation of a sixth embodiment according to FIG. 10,

FIG. 12 is a representation of a seventh embodiment according to FIG. 10,

FIG. 13 is a representation of an eighth embodiment according to FIG. 10,

FIG. 14 is a representation according to FIG. 10, wherein the gas-outlet opening 10 is arranged on a movable plate 25′,

FIG. 15 is a representation according to FIG. 3 of a tenth embodiment, in which two gas-outlet openings 10, 10′ with different diameters are provided,

FIG. 16 shows a ninth embodiment in a representation according to FIG. 3, wherein three zones Z1, Z2, Z3 are marked with additional auxiliary lines,

FIG. 17 shows the dopant concentration in a layer depending on angle α, and

FIG. 18 is a representation according to FIG. 9 of a nineth embodiment of the invention.

### DETAILED DESCRIPTION

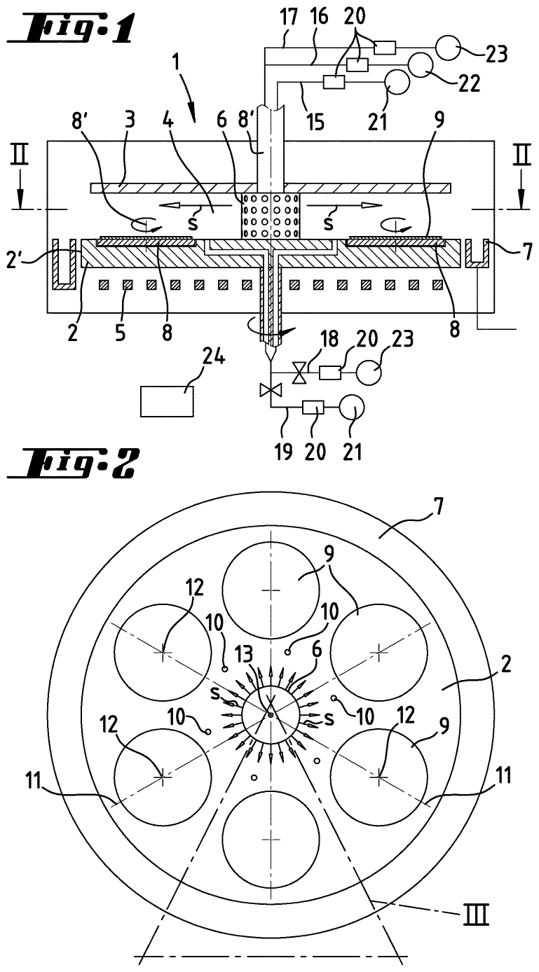

The CVD reactor represented in FIGS. 1 and 9 has a housing 1 and is part of a coating device which additionally includes a control device 24 and a gas supply system.

The gas supply system has a multiplicity of feed lines 15, 16, 17, 18, 19 through which reactive gases provided by gas sources 21, 22, 23 can be transported together with an inert gas, the gas source of which is not shown, to a process chamber 4 arranged in the housing 1. A gas source 21 provides a carbon-containing gas, a gas source 22 a silicon-containing gas and a gas source 23 a nitrogen-containing gas, wherein these gases may be methane, propane, silane, disilane, trichlorosilane, nitrogen, ammonia or the like. In the supply lines 15, 16, 17, 18, 19 there are valves (not shown) and mass flow controllers 20 with which the gas flow can be adjusted. The gas flows can be adjusted using the control device 24. For this purpose, the control device 24 contains a programmable control computer that can process a recipe stored in the control device 24, and in which values for the gas flows are included. The recipe enables several consecutive process steps to be carried out automatically. One or more layers containing SiC and doped with nitrogen can be deposited on a substrate, for example a SiC substrate. However, the device is also suitable for depositing other material systems.

The CVD reactor contains a susceptor 2 which extends in a horizontal plane and can be heated to a process temperature of over 1500 degrees Celsius with a heating device 5 arranged underneath the susceptor 2. A gas-inlet element 6 is provided with which the reactive gases can be fed into the process chamber 4. The supply lines 15, 16, 17 for gases containing carbon, silicon and nitrogen open into the gas-inlet element 6. The gas-inlet element 6 includes a gas-outlet surface that is porous or has a large number of openings that are evenly distributed and in particular of the same size, through which a gas mixture of the previously described gases can enter the process chamber 4. In the embodiment, the gas-inlet element 6 has a single gas-inlet zone through which a homogeneous mixture of the gases flows into the process chamber 4, forming a homogeneous laminar flow. In embodiments not shown, several gas-inlet zones may be arranged one above the other, through which various mixtures of the gases flow into the process chamber 4, each as a homogeneous laminar flow.

The CVD reactor is operated in such a way that a homogeneous, laminar flow profile is formed over at least part of the height of the cross-sectional area, preferably over the entire cross-sectional area of the process chamber 4. In the embodiment shown in FIG. 1, the flows of the first gas flow which emerges from the gas-inlet element 6, extend in a star shape relative to a center 13, which is located inside the gas-inlet element 6. Here, the gas-outlet surface extends on a cylindrical surface which extends from a bottom of the process chamber 4 formed by the susceptor 2 up to a process chamber ceiling 3. In the embodiment represented in FIG. 9, the gas-outlet surface may be a rectangular surface, wherein the width of the gas-outlet surface extending in the flow direction S is greater than a diameter B2 of the substrate 9.

Downstream of the first gas flow, the susceptor 2 has storage spaces, each for one substrate 9. In the embodiment, the storage spaces are each formed by a substrate holder 8 which lies in a pocket of the susceptor 2. Supply lines (not shown), each for one purge gas flow, consisting of the inert gas, for example hydrogen, open into the bottom of the pocket.

This purge gas flow creates a gas cushion beneath the substrate holder 8, which lifts the substrate holder 8 and causes it to rotate about its axis 8′.

Radially outside an edge 2′ and opposite the gas-inlet element 6, a gas-outlet element 7 is provided, through which the process gas fed into the process chamber 4 via the gas-inlet element 6 or decomposition products of the process gas can be transported out of the process chamber 4. This is done with a pump (not shown) that can generate a negative pressure inside the process chamber 4.

In a zone through which the first gas flow flows preferably evenly and homogeneously and which is located downstream of the gas-inlet element 6 and upstream of the substrate holder 8 and the substrate 9, a gas-outlet opening 10 is arranged, through which a second gas flow can be fed into the process chamber. The position of the gas-outlet opening 10 influences the effective site of a second gas flow that flows through the gas-outlet area of the gas-outlet opening 10 into the process chamber 4, and which contains a gas that influences the layer composition, preferably the dopant concentration within the layer, which may be, for example, nitrogen or one of the carbon-containing reactive gases mentioned above. The second gas flow flows through the process chamber 4 along a flow line 14. The position of the flow line 14 relative to a midline 11, which extends in the flow direction S of the first gas flow through the middle point 12 of the substrate 9, influences the incorporation of dopant into the layer at different radial distances relative to the middle point 12. The flow line 14 extends along the flow direction S of the first gas flow.

Supply lines 18, 19 are provided, with which the second gas flow can be fed into the process chamber 4. The supply lines 18, 19 are connected to a carbon gas source 21 or a nitrogen gas source 23. The supply lines 18, 19 open into one or more gas-outlet openings 10, 10′, 10″.

FIG. 2 shows a plan view of the susceptor 2 of the first embodiment, which is surrounded by an annular gas-outlet element 7. Six substrates 9 are arranged in uniform circumferential distribution around the center 13. In other embodiments, the number of substrates 9 may be smaller or larger. Notional midlines 11 extend through the middle points 12 of the substrates 9 and run parallel to the flow direction S of the first gas flow, and thus through the center 13. A star-shaped array of flow lines extends symmetrically around the center 13.

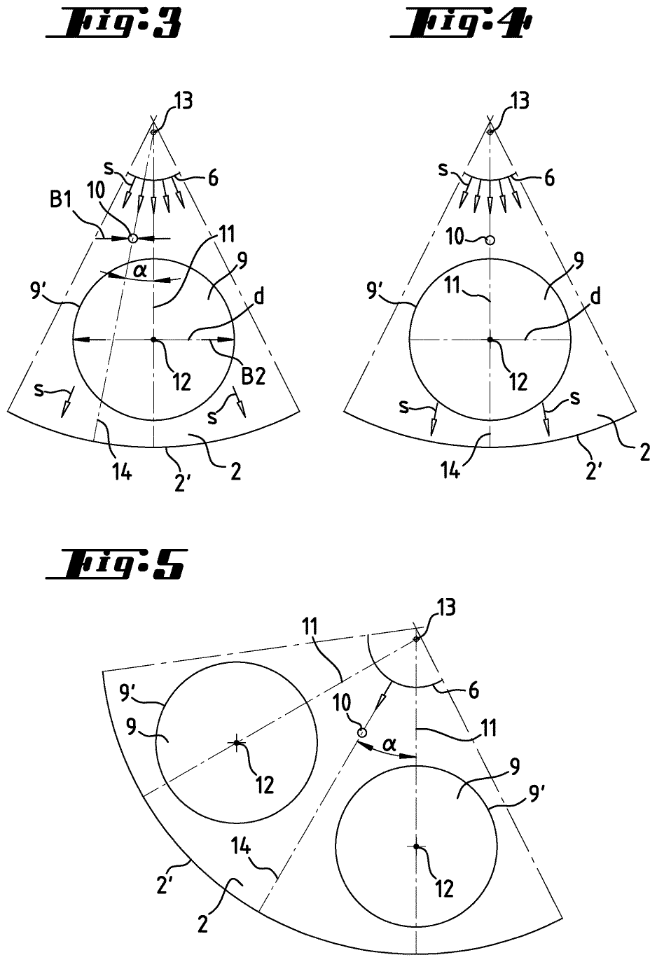

In the first embodiment, represented in FIG. 2, which is shown enlarged in FIG. 3, the gas-outlet openings 10 are arranged offset with respect to the midline 11. A straight line running through the center 13 and through the middle point of the gas-outlet opening 10 forms a flow line 14 along which the second gas flow exiting the gas-outlet opening 10 flows. Here, the angle α between the midline and the flow line 14 is selected such that the flow line 14 passes over one of the two halves of the substrate 9 into which the midline 11 divides the substrate surface. Depending on the size of the angle α, the radial position of an effective site of the second gas flow changes relative to the middle point 12 of the substrate 9.

The circular gas-outlet opening in the embodiment has a diameter B1 that is significantly smaller than the diameter B2 of the circular substrate 9. The diameter of the gas-outlet surface of the gas-outlet opening 10 is preferably smaller than half, a third, a quarter, a fifth or a sixth of the diameter of the substrate 9. However, the diameter of the gas-outlet opening 10 may also be smaller than a tenth of the diameter of the substrate. The smaller the width B1 of the gas-outlet surface of the gas-outlet opening 10 measured transversely to the flow direction S is, the smaller the width of the second gas flow emerging from it is, which spreads transversely to the flow direction as a result of diffusion or the star-shaped arrangement of the flow lines of the main flow. The smaller the ratio of width B1 of the gas-outlet surfaces to a width B2 of the substrate 9 measured transversely to the flow direction S is, the more locally precisely the dopant incorporation into the layer can be influenced with the second gas flow.

In the second embodiment, shown in FIG. 4, the gas-outlet opening 10 is located on the midline 11, so that the second gas flow emerging from it runs through the middle of the substrate 9.

In the embodiment shown in FIG. 5, the gas-outlet opening is located approximately on an angle bisector of two midlines 11 that run through the middle points 12 of two adjacent substrates 9, so that the flow line 14 passes through the gap between two substrates 9. The second gas flow is directed precisely past the substrates 9 here, so that the gas contained in the second gas flow that influences the dopant incorporation only acts in the region of the edge 9′ of the substrate.

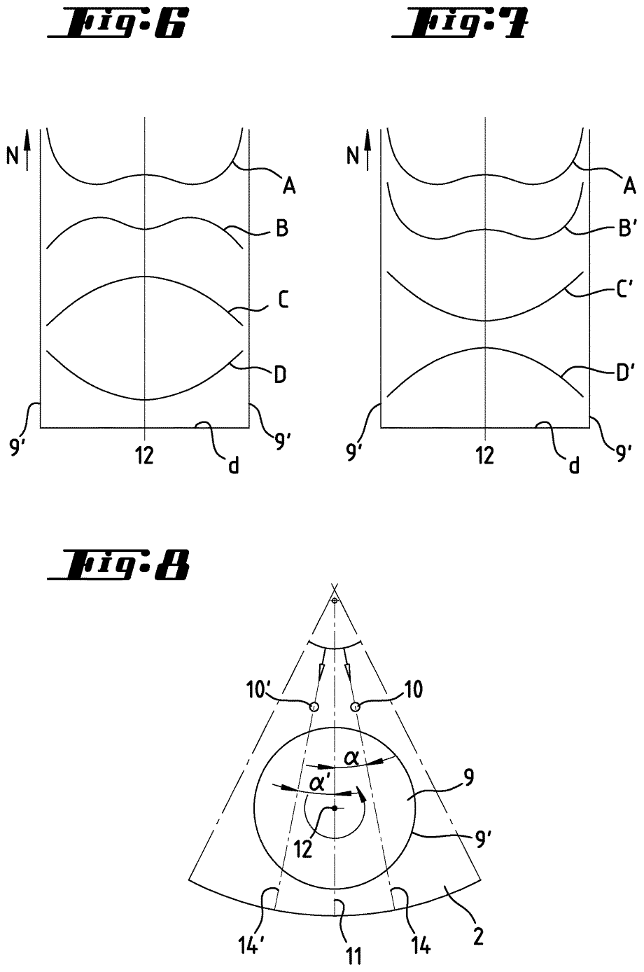

FIG. 6 is a schematic representation of the effects of the arrangements of the gas-outlet openings 10 in the previously described embodiments.

The W-shaped curve A shows the dopant concentration that a layer deposited on the substrate 9 without the second gas flow has along a line d through the middle point 12, with a dopant additionally being fed into the process chamber through the gas-inlet element 6. Due to the rotation of the substrate 9 during the deposition of the layer, the dopant concentration has a rotational symmetry. However, it has a maximum in the region of the middle point and in the region of the edges of the substrate 9. There is a minimum between each.

Curve B shows the influence of a second gas flow that contains a reactive gas, for example nitrogen, that enhances incorporation of the dopant, on the radial dopant concentration. In the region between middle point 12 and edge 9′ of the substrate 9, where the effective site is in FIG. 3, there is maximum incorporation of the dopant. In this way, the minima represented in curve A can be compensated.

Curve C shows the influence of a second gas flow that contains a reactive gas that enhances dopant incorporation, wherein the gas-outlet opening 10 is located in accordance with the embodiment shown in FIG. 4, i.e. on the midline 11. Here, the effective site is in the middle, so that a maximum of the dopant concentration is formed in the region of the middle point 12.

Curve D shows the influence of a second gas flow that contains a reactive gas that enhances dopant incorporation, wherein the gas-outlet opening 10 is located in accordance with the embodiment shown in FIG. 5, so that a flow line 14 is formed between two substrates 9. Here, only the edge region of the two substrates 9 is influenced by the second gas flow, because the effective site is between the substrates 9. The maxima here are at the edge 9′, whereas a minimum 12 is formed in the region of the middle point.

FIG. 7 is a schematic representation of the effects of the arrangements of the gas-outlet openings 10 in the embodiments described in FIGS. 3 to 5, although now the second gas flow contains a reactive gas that inhibits the incorporation of dopants, for example a carbon-containing gas.

Here too, the W-shaped curve A shows the dopant concentration that a layer deposited on the substrate 9 without the second gas flow has along the line d through the middle point 12, although here too a dopant is fed in through the gas-inlet element 6. Here too, the dopant concentration is rotationally symmetrical due to the rotation of the substrate 9 during the deposition of the layer.

Curve B′ shows the effect of the second gas flow in an arrangement of the gas-outlet opening 10 according to FIG. 3. Here, minima form in the region between the middle point 12 and the edge 9′.

Curve C′ shows the effect of the second gas flow in an arrangement of the gas-outlet opening 10 according to FIG. 4. Here, the reactive gas that reduces the dopant incorporation causes a minimum in the region of the middle point and maxima in the region of the edges 9′.

Curve D′ shows the effect of the second gas flow in an arrangement of the gas-outlet opening 10 according to FIG. 5. Here, the reactive gas that reduces the dopant incorporation causes the formation of a maximum in the region of the middle point 12 and the formation of a minimum in the region of each of the edges 9′.

Through a targeted selection of the angle α and/or a targeted ratio between the gas influencing the dopant incorporation that exits the gas-outlet opening 10, and the reactive gas influencing the dopant incorporation that exits the gas-inlet element 6, the respective curve A can be modified with the second gas flow in such a way that it is as flat as possible. It is thus possible to raise the curve in the region of its minima or lower it in the region of its maxima.

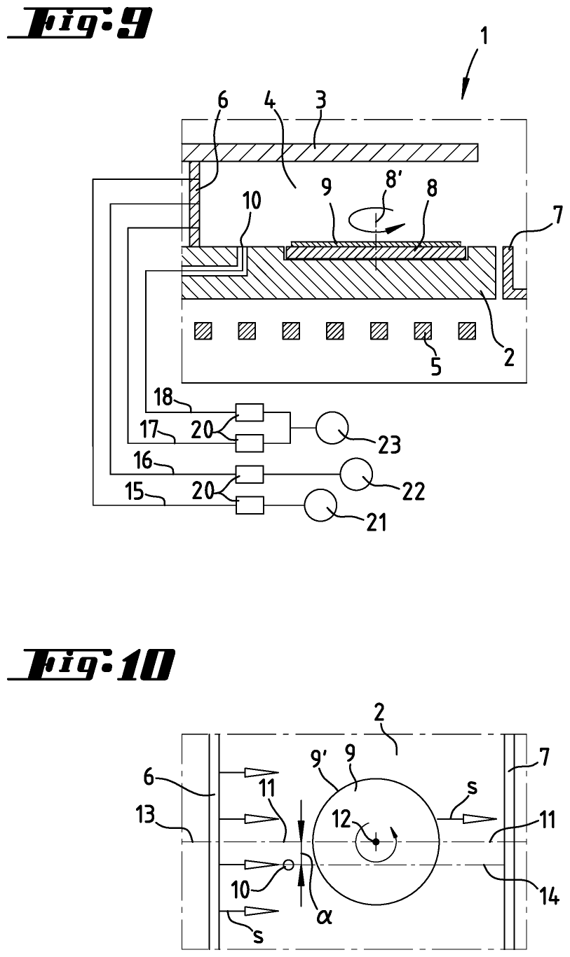

It is possible to allow a gas flow that influences the dopant concentration within the layer to flow through the gas-inlet element 6 and through the gas-outlet opening 10 at the same time. However, it is also provided that the gas flow that influences the dopant concentration only flows through the gas-outlet opening 10. In the embodiment shown in FIG. 8, multiple gas-outlet openings 10, 10′ are provided, which are arranged on different flow lines 14, 14′ from each other, and through which the same or different gas flows can emerge. With these two second gas flows, the dopant incorporation can be influenced in targeted manner at two different radial positions on the substrate 9. The angles α, α′ may be the same or different.

FIG. 9 shows a second embodiment of a CVD reactor in which the first gas flow flows linearly in the horizontal direction through the process chamber 4 arranged in the housing 1. The substrate 9 lies in the middle of the susceptor 2 and is equidistant from the two walls of the process chamber 4 in a direction transverse to the flow direction S. A midline 11 passes through a center 13 of the gas-inlet element 6 and through the middle point 12 of the substrate 9 or of a substrate holder 8 supporting the substrate. The midline 11 has the direction of the flow direction S.

A homogeneous laminar main gas flow, which may or may not contain a dopant, emerges from the gas-inlet element 6. The gas flow flows through the process chamber 4 in such a way that a SiC layer is deposited on the substrate 9. A further gas flow influencing the dopant concentration is fed into the process chamber through the gas-outlet surface of an additional gas-outlet opening 10, wherein in the embodiment shown in FIG. 10 the gas-outlet opening 10 may have a distance a from the midline 11, so that the flow line 14 extending parallel to the midline 11 passes over one of the two halves of the substrate 9.

The embodiment shown in FIG. 18 corresponds substantially to the embodiment shown in FIG. 9. The gas source 23 may contain N₂. A gas source 23′ may contain ammonia. The mass flow controllers 20 are adjusted in such a way that ammonia flows through the uppermost gas-inlet zone through the gas-inlet element 6 into the process chamber 4. In a SiC layer deposited on a substrate 9 that is lying on a rotating substrate holder 8, ammonia produces a bell-shaped dopant profile which falls towards the edge, as shown by line C in FIG. 6.

N₂ is fed into the bottom of the process chamber 4 through the feed line 18, so that it emerges from the gas-outlet opening 10. Ammonia produces a trough-shaped dopant profile which rises towards the edge, as shown by curve A in FIG. 6. By appropriate selection of the settings of the mass flow controllers 20, i.e. a suitable ratio between the mass flows of N₂ and ammonia, an almost flat dopant profile can be produced in the SiC layer that is deposited on the substrate 9.

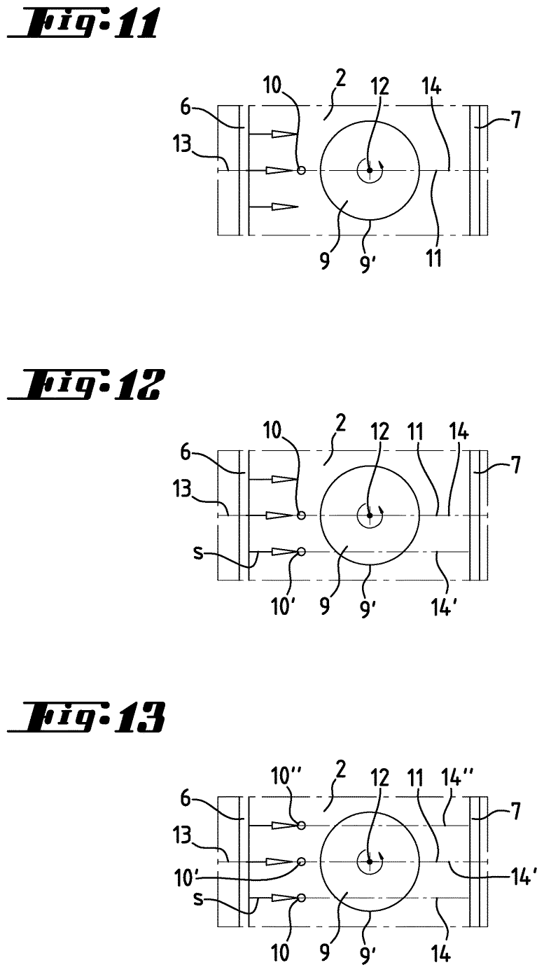

In the embodiment shown in FIG. 11, the gas-outlet opening 10 is located on the midline 11.

In the embodiment shown in FIG. 12, two gas-outlet openings 10, 10′ are provided, wherein one gas-outlet opening 10 is arranged on the midline 11 and a second gas-outlet opening 10′ is offset from the midline 11.

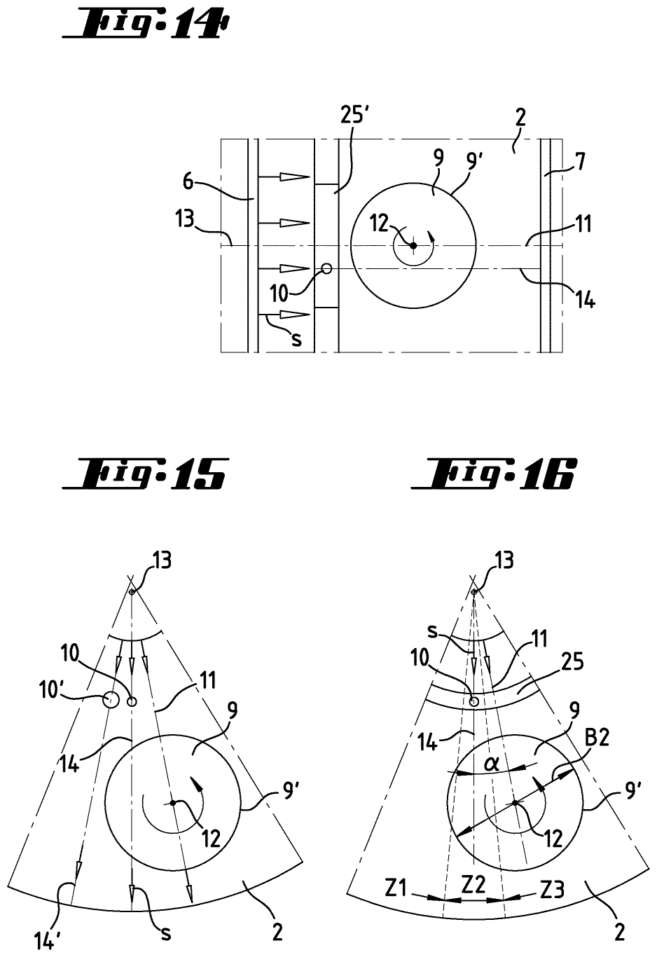

In the embodiment shown in FIG. 13, three gas-outlet openings 10, 10′, 10″ are provided, which, as also in the embodiment shown in FIG. 12, lie on a line that extends transversely to the flow direction S. The flow lines 14′, 14″ passing through the gas-outlet openings 10′, 10″ may run over the edge 9′ of the substrate 9.

Here too, the dopant concentration within the layer may be influenced locally by a targeted selection of the gas influencing the dopant concentration and its mass flow or ratio to a mass flow of a gas influencing the dopant concentration that enters through the gas-inlet element, wherein the effects of the individual second gas flows with regard to the position of the gas-outlet opening 10, 10′, 10″ relative to the midline 11 and the quality of the gas are illustrated in FIGS. 6 and 7. If multiple gas-outlet openings 10, 10′, 10″ are provided, they do not have to follow an exact line transversely to the flow direction S. They may also each be at a different distance from the gas-inlet element 6, so that the gas flows flowing from the gas-outlet openings 10, 10′, 10″ are fanned out in a different way at their points of action on the substrate 9.

The embodiment represented in FIG. 14 shows a plate 25′ which may be moved transversely to the flow direction S and includes the gas-outlet opening 10. By moving the plate 25, the distance of the flow line 14 from the midline 11 can be adjusted individually.

FIG. 15 shows a tenth embodiment of the invention, wherein one gas-outlet opening 10, 10′ each is arranged upstream of the substrate 9 on two flow lines 14, 14′, both of which pass over the surface of the substrate 9. The gas-outlet opening 10′ has a larger diameter than the gas-outlet opening 10.

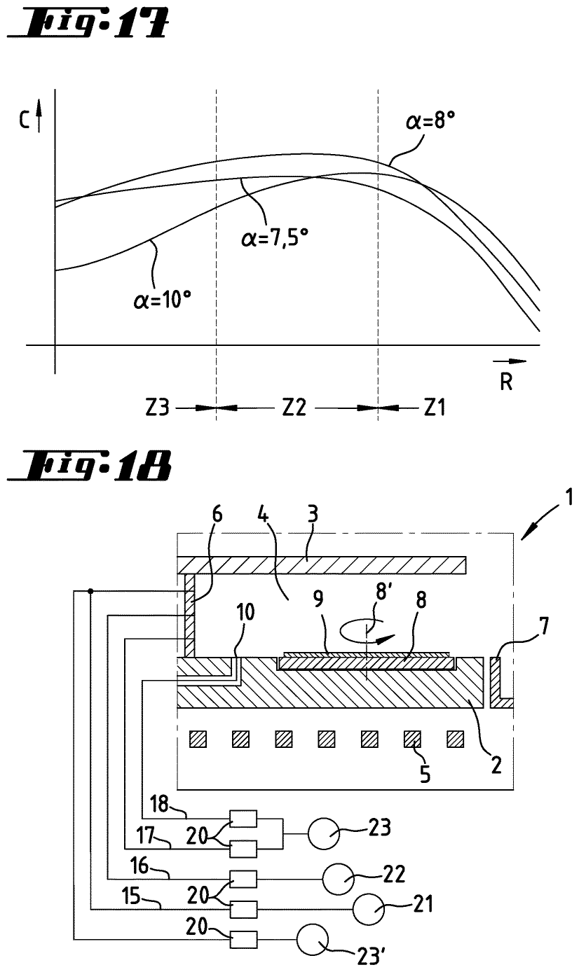

The eleventh embodiment shown in FIG. 16 shows a gas-outlet opening 10 which is offset from the midline 11 by an angle α of approximately 8 to 10 degrees. Here, the substrate 9 has a diameter B2 such that tangents applied at the edge 9′ and passing through the center 13 enclose an angle of 70 degrees. In such an arrangement, it is advantageous if the angle α is between 5 and 10 degrees. The angle may preferably be 8.5 degrees. The reference numeral 25 here represents a ring with multiple gas-outlet openings 10. The angle α can be adjusted by rotating the ring 25 about the center 13.

FIG. 17 shows the influence of the angle α on the dopant concentration C, which is plotted along the radius R of a substrate 9. Zones Z1, Z2, Z3 can be defined, which are also shown in FIG. 16, in which the dopant incorporation can be influenced in targeted manner. Zone Z1 extends, for example, from the edge 9′ of the substrate into a first region of one half of the substrate. Zone Z2 extends over an angular range that runs over the middle of one half of substrate 9. Zone Z3 extends adjacent to this beyond the middle point of the substrate. The maximum influence on the dopant incorporation is in zone Z2, which extends over a region that is between 30 mm and 60 mm distant from the middle point 12.

The minima and maxima of curve A can be neutralized in a targeted manner.

With the arrangement and size of the gas-outlet surface of the gas-outlet opening according to the invention, the gas stream exiting the gas-outlet opening, which contains a gas that influences the dopant concentration, can be used to specifically influence the dopant incorporation in a zone that lies between the middle point of the substrate and the edge of the substrate.

The embodiment describes the local influence on the dopant incorporation.

However, the invention also includes methods with which ternary or quaternary semiconductor layers are deposited, wherein the layer composition can be influenced locally by the second gas flow. In this case, no dopant is fed into the process chamber through the gas-outlet opening 10, 10′, 10″, but rather one of the starting materials forming the crystal.

Such a material system may be the material system GaInAsP.

The above notes are intended to explain the inventions covered by the application as a whole, each of which also develop the prior art independently, at least through the following combinations of features, wherein two, several or all of these combinations of features may also be combined, namely:

A method which is characterized in that the width B1 of the gas-outlet opening 10, 10′, 10″ extending transversely to the flow direction S is smaller than the width B2 of the substrate 9 extending transversely to the flow direction.

A method which is characterized in that a flow line 14 passing through the gas-outlet opening 10, 10′, 10″ along the flow direction S is offset by an angle α or by a distance a with respect to a midline 11 passing through the middle point 12 of the substrate 9 in the flow direction S.

A method which is characterized in that the flow line 14 passes over the substrate 9 between the middle point 12 and the edge 9′ of the substrate 9, or that the flow line 14 runs past the substrate 9 outside the edge 9′ of the substrate 9, or that the flow line 14 passes through a gap between two substrates 9 arranged next to one another.

A method which is characterized in that the width B1 of the gas-outlet opening 10, 10′, 10″ running transversely to the flow direction S is smaller than half, a third, a quarter, a fifth or a sixth of the width B2 of the substrate 9 running transversely to the flow direction S.

A method which is characterized in that the substrate 9 rests on a substrate holder 8, which is driven in rotation about an axis of rotation 8′ and/or that the substrate 9 is supported by a susceptor 2 which is brought to a process temperature by a heating device 5 and/or that the gas-inlet element 6 forms the center 13 of the susceptor 2 and generates a first gas flow that flows in the radial direction relative to the center 13.

A method which is characterized in that the first gas flow flows through the process chamber 4 along parallel or star-shaped flow lines.

A method which is characterized in that the first gas flow fed in through the gas-inlet element 6 contains at least one carbon-containing and silicon-containing gas for depositing a SiC layer, and that a carbon-containing or nitrogen-containing gas flows into the process chamber 4 through the gas-outlet opening 10, 10′, 10″.

A method which is characterized in that a plurality of gas-outlet openings 10, 10′, 10″ are arranged in the flow direction S between the gas-inlet element 6 and the substrate 9.

A device which is characterized in that the gas-outlet opening 10 is connected to a source 23, 21 of a gas influencing the layer composition or the dopant concentration within the layer.

A device which is characterized by a control device 24, which has a control program that controls the device according to any one of claims 1 to 8.

All of the features disclosed are essential to the invention (individually, but also in combination with each other). The content of the disclosure of the associated/attached priority documents (copy of the prior application) is hereby included in the disclosure of the application in its entirety, also for the purpose of including features of these documents in claims of the present application. The subclaims characterize, even without the features of a referenced claim, with their features independent inventive developments of the prior art, in particular in order to make divisional applications based on these claims. The invention specified in each claim may additionally have one or more of the features provided in the above description, in particular those designated with reference numbers and/or specified in the list of reference numbers. The invention further relates to designs in which individual features mentioned in the above description are not implemented, in particular insofar as they are clearly dispensable for the respective intended use or can be replaced by other technically equivalent means.

### LIST OF REFERENCE SYMBOLS

1 Housing
2 Susceptor
2′ Edge
3 Process chamber ceiling
4 Process chamber
5 Heating device
6 Gas-inlet element
7 Gas-outlet element
8 Substrate holder
8′ Axis of rotation
9 Substrate
9′ Edge
10 Gas-outlet opening
10′ Gas-outlet opening
10″ Gas-outlet opening
11 Middle line, midline
12 Middle point
13 Center
14, 14′, 14″ Flow line
15, 16, 17, 18, 19 Supply line
20 Mass flow controller
21 Gas source, carbon
22 Gas source, silicon
23 Gas source, nitrogen
24 Control device
25 Ring
25 Plate
d Line through the middle point 12
B1 Width of the gas-outlet opening 10, 10′, 10″
B2 Width (diameter) of the substrate 9
A Dopant concentration
B, B′, C, C′, D, D′ Dopant concentration
S Flow direction of the first gas flow

What is claimed is:

1. A method for depositing a layer on a substrate (9), comprising:
feeding a homogeneous first gas flow into a process chamber (4), brought to a process temperature, via a gas-inlet element (6), wherein the first gas flow flows in a flow direction (S) over the substrate (9), and contains one or more reactive gases, decomposition products of which form the layer
feeding a second gas flow into the process chamber (4) through a gas-outlet surface of a gas-outlet opening (10, 10′, 10″) arranged downstream of the gas-inlet element (6) and upstream of the substrate (9), wherein the second gas flow contains at least one reactive gas which influences at least a composition of the layer or a dopant concentration within the layer,
wherein a the width (B1) of the gas-outlet opening (10, 10′, 10″) extending transversely to the flow direction (S) is smaller than the-a width (B2) of the substrate (9) extending transversely to the flow direction, and
wherein a flow line (14) passing through the gas-outlet opening (10, 10′, 10″) along the flow direction (S) is offset by an angle (α) or by a distance (a) with respect to a midline (11) extending in the flow direction (S) through a middle point (12) of the substrate (9).

2. (canceled)

3. The method of claim 1, wherein one of:
the flow line (14) passes over the substrate (9) between middle point (12) and an edge (9′) of the substrate (9),
the flow line (14) runs past the substrate (9) outside the edge (9′) of the substrate (9), or
the flow line (14) passes through a gap between two-the substrate (9) and an adjacent substrate (9).

4. The method of claim 1, wherein the width (B1) of the gas-outlet opening (10, 10′, 10″) extending transversely to the flow direction (S) is smaller than half of the width (B2) of the substrate (9) extending transversely to the flow direction (S).

5. The method of claim 1, wherein the substrate (9) rests on a substrate holder (8) which is driven to rotate about an axis of rotation (8′).

6. The method of claim 1, wherein the substrate (9) is supported by a susceptor (2) which is brought to the process temperature by a heating device (5).

7. The method of claim 1,
wherein the gas-inlet element (6) forms a center (13) of the susceptor (2) and generates the first gas flow, and
wherein the first gas flow flows in a radial direction relative to the center (13).

8. The method of claim 1, wherein the first gas flow flows through the process chamber (4) along parallel or star-shaped flow lines.

9. The method of claim 1, wherein the first gas flow fed in through the gas-inlet element (6) contains at least one carbon-containing and silicon-containing gas for depositing a SiC layer, and a carbon-containing or a nitrogen-containing gas flows into the process chamber (4) through the gas-outlet opening (10, 10′, 10″).

10. The method of claim 1, wherein the gas-outlet opening (10, 10′, 10″) is part of a plurality of gas-outlet openings (10, 10′, 10″) arranged in the flow direction (S) between the gas-inlet element (6) and the substrate (9).

11. The method of claim 1, further comprising:
feeding ammonia into the process chamber (4) through the gas-inlet element (6); and
feeding nitrogen gas, N₂, into the process chamber (4) through the gas-outlet opening (10, 10′, 10″).

12. A device for depositing a layer on a substrate (9), the device comprising:
a process chamber (4);
a housing (1) in which the process chamber (4) is arranged;
a susceptor (2) disposed in the process chamber (4);
a gas-inlet element (6) disposed in the process chamber (4) and configured to feed a first process gas into the process chamber (4);
a gas-outlet element (7) for transporting the first process gas out of the process chamber (4);
a substrate holder (8); and
a gas-outlet opening (10, 10′, 10″) arranged in a zone downstream of the gas-inlet element (6) and upstream of the substrate holder (8),
wherein the gas-outlet opening (10, 10′, 10″) has a gas-outlet surface, whose width (B1) extending transversely to a flow direction (S) of the first process gas through the process chamber (4) is smaller than a width (B2) of the substrate holder (8) or the substrate (9) extending transversely to the flow direction (S),
wherein the gas-outlet opening (10, 10′, 10″) is configured to feed a further gas into the process chamber (4),
wherein the gas-outlet opening (10, 10′, 10″) is connected to a source (23, 21) of a gas influencing a layer composition or a dopant concentration within the layer,
wherein a flow line (14) passing through the gas-outlet opening (10, 10′, 10″) along the flow direction (S) is offset by an angle (α) or by a distance (a) with respect to a midline (11) extending in the flow direction (S) through a middle point (12) of the substrate (9).

13. The device of claim 12, further comprising a control device (24) with a control program that controls the device.

14. (canceled)

15. The method of claim 1, wherein the width (B1) of the gas-outlet opening (10, 10′, 10″) extending transversely to the flow direction (S) is smaller than a third of the width (B2) of the substrate (9) extending transversely to the flow direction (S).

16. The method of claim 1, wherein the width (B1) of the gas-outlet opening (10, 10′, 10″) extending transversely to the flow direction (S) is smaller than a quarter of the width (B2) of the substrate (9) extending transversely to the flow direction (S).

17. The method of claim 1, wherein the width (B1) of the gas-outlet opening (10, 10′, 10″) extending transversely to the flow direction (S) is smaller than a fifth of the width (B2) of the substrate (9) extending transversely to the flow direction (S).

18. The method of claim 1, wherein the width (B1) of the gas-outlet opening (10, 10′, 10″) extending transversely to the flow direction (S) is smaller than a sixth of the width (B2) of the substrate (9) extending transversely to the flow direction (S).
